(19) United States
(12) Patent Application Publication
(10) Pub. No.: US 2013/0077249 A1
(43) Pub. Date: Mar. 28, 2013

(54) OVERMOLDED IN-LINE PHOTOVOLTAIC CURRENT REGULATING AND HEAT SINK DEVICE

(71) Applicant: Edmund John GUINN, Winnipeg (CA)

(72) Inventor: Edmund John GUINN, Winnipeg (CA)

(73) Assignee: AMPHENOL TECHNICAL PRODUCTS INTERNATIONAL, Winnipeg (CA)

(21) Appl. No.: 13/245,432

(22) Filed: Sep. 26, 2011

(51) Int. Cl. H05K 7/20

(52) U.S. Cl. 361/705

(57) ABSTRACT

An overmolded in-line photovoltaic current regulating and heat sink device includes one or more diode elements connected at one or more leads to coils of electrically conductive material. The coils serve a dual purpose; they act as heat sinks to draw heat away from the diode and conduct it to the outside environment; and they act as inductor coils to regulate current through the device. These coils can either be of air core or ferromagnetic core construction. On the opposite end of the diode leads, the coils are connected to either a wire lead protruding from the device or a terminal housed in a connector. The entire assembly is encapsulated in a thermoplastic, thermoset, or combination thereof that maintains intimate thermal contact with the diode and coils. The device may include one or more fuse elements in place of, or in addition to, the one or more diode elements.

### BACKGROUND OF THE INVENTION

1. Field of Invention

The present invention relates to photovoltaic cell protection, in particular, the protection of photovoltaic cells, strings, or arrays from overheating caused by shading or other light obstruction. Such protection is achieved through the use of blocking or bypass diode elements.

2. Description of the Related Art

Historically, blocking and bypass diodes were housed primarily in junction boxes and combiner boxes, or integrated directly into photovoltaic modules. The in-line diode device allows installers and manufacturers to remove the diodes from the combiner boxes and junction boxes and, in some cases, eliminate combiner boxes all together. This development is known and being used in the industry.

Photovoltaic assemblies often include fuses, which serve to protect photovoltaic cells, strings, or arrays from excessive currents that may cause damage to the components of the circuits through which the currents pass. In-line fuse devices may be similar in physical structure to in-line diode devices.

Existing in-line diodes and in-line fuses are bulky and lack effective instruments for dissipating the heat generated when the diode or fuse is passing current. The typical method for dissipating heat is by use of a heat sink constructed of heat pipes, metallic blocks, or cylinders with fins. These designs are both costly and large, and are not practical for use in an in-line diode or in-line fuse system.

The use of inductor coils to regulate current is known and employed in many industries. Inductors can be air cored or can contain a core of magnetic material (typically ferrite) to increase the inductance of the coil. The current conducting material is wound around the core and a magnetic field is created by the current passing through the conductor. This magnetic field stores energy and effectively resists changes in current through the device.

However, none of those prior devices is adapted to regulate current in the device while optimizing heat transfer from the device without employing a large, costly, or otherwise impractical design. Accordingly, there exists a need for such a device.

In particular, there exists a need for a system that provides an in-line diode or an in-line fuse, wherein coils within the device both regulate current, and act as heat sinks, dissipating heat along the length of the coils to the adjacent material and consequently to the outside environment.

### SUMMARY OF THE INVENTION

Accordingly, it is a principal object of the present invention to provide a device configured to provide photovoltaic cell protection by way of an in-line diode or in-line fuse.

It is another principal object of the present invention to provide a device comprising an in-line diode or in-line fuse, wherein the device is configured to regulate the current passed through the device.

It is still another principal object of the present invention to provide a device comprising an in-line diode or in-line fuse, wherein the device is configured to dissipate heat generated by the diode or fuse.

A key feature of the invention is the use of current conducting material that conducts heat from a diode element or fuse element to an encapsulating material and consequently to the outside environment. The current conducting material may be wound into a coil so that it simultaneously acts as an inductor, having the inherent ability to regulate current passing through it. The invention, however, does not require that the current conducting material be wound into a coil, nor does it require that the current conducting material exhibit inductive properties. Whereupon this specification discloses a coil or coils, it should be understood that alternate configurations of current conducting material may be used to achieve heat conducting characteristics similar to those exhibited by a coil or coils.

One or more diode or fuse elements are fixed to one end of the coil via soldering, welding, brazing, crimping, or other joining means that will ensure sound thermal and electrical contact. The other lead(s) from the diode or fuse element(s) may be joined to the end of another coil on the other side of the device, or in the case where only one coil is employed, to a wire protruding from the device or to an electrical terminal housed in a connector body. The free end(s) of the coil(s) are similarly joined to a wire protruding from the device or to a terminal. The protruding wires or terminals are connected to the wiring system of a photovoltaic array.

The assembly of diode(s), or fuse(s), and coil(s) is encapsulated in an electrically insulative material, which maintains intimate thermal contact with the diode(s), or fuse(s), and coil(s). Preferably, the encapsulating material is formed of a thermoplastic, thermoset, or combination thereof, which may also be referred to as a plastic or resin. Due to the relatively low thermal conductivity of the encapsulating material (0.12 to 0.63 W/m·K) as compared to typical current conducting materials (23 to 388 W/m·K), the coils need sufficient surface area in contact with the encapsulating material to transfer the required heat to the material without simply transferring the heat directly through the conductor and into the adjacent wire connection or terminal. The coils must be of sufficient length to allow for optimal conduction of heat to the encapsulating material, without being too long so as to cause excessive electrical resistance across the device. The parameters of coil wire diameter, coil wire length, overall coil length, outside coil diameter, number of coil turns and turn pitch are all optimized to ensure maximum heat transfer, minimal electrical resistance and minimum cost. These parameters may vary depending on the current ratings of the diode(s) or fuse(s) employed by the device.

The outside surface of the encapsulating material may have features, such as fins or fin-shaped embossments, disposed thereon to increase the outside surface area and improve the convective heat transfer properties. Due to the low thermal conductivity of the encapsulating material; the use of long, protruding heat sink fins is impractical and the fin length may be shorter than a typical metallic heat sink.

A major advantage of this invention is its ability to optimize the transfer of heat to the surrounding environment by efficiently distributing the heat through the device. Another advantage of this invention is its ability to regulate current fluctuations passing through it, ensuring that the diode or fuse element, and any other devices to which this device is connected, experience steady current.

Briefly described, those and other objects and features of the present invention are accomplished, as embodied and fully described herein, by a device comprising: a circuit element having a first lead and a second lead; a first coil formed of electrically conductive material, the first coil electrically connected to the first lead; and an insulative material, the insulative material encapsulating the circuit element and the first coil, and the insulative material maintaining intimate thermal contact with the circuit element and the first coil, wherein the first coil is configured to draw heat away from the circuit element and into the insulative material.

The system may include one or more diodes, may include a fuse, or may include a combination of diodes and fuses. The system may include one or more coils having either air cores or ferromagnetic cores. The system may include either wires or terminals to facilitate connection to the wiring system of a photovoltaic array. The system may include insulative material formed of a thermoplastic, thermoset, or combination thereof having features, such as fins or fin-shaped embossments, disposed thereon to aid in the transfer of heat from the device to the surrounding environment.

With those and other objects, advantages, and features of the invention that may become hereinafter apparent, the nature of the invention may be more clearly understood by reference to the following detailed description of the invention, the appended claims and to the several drawings attached herein.

### BRIEF DESCRIPTION OF THE DRAWINGS

FIG. 1 is a perspective view of a current regulating device according to the present invention.

FIG. 2 is a perspective view of the current regulating device of FIG. 1, further depicting connector bodies attached to components of the device.

FIG. 3 is a perspective view of the current regulating device of FIG. 2, further depicting an overmold encapsulating components of the device.

FIG. 4 is a perspective view of a current regulating device according to an alternative embodiment of the present invention.

FIG. 5 is a perspective view of a current regulating device according to another alternative embodiment of the present invention.

FIG. 6 is a side elevation view of a coil according to the present invention.

FIG. 7 is a front elevation view of a coil according to the present invention.

### DETAILED DESCRIPTION OF THE PREFERRED EMBODIMENTS

Several preferred embodiments of the invention are described for illustrative purposes, it being understood that the invention may be embodied in other forms not specifically shown in the drawings.

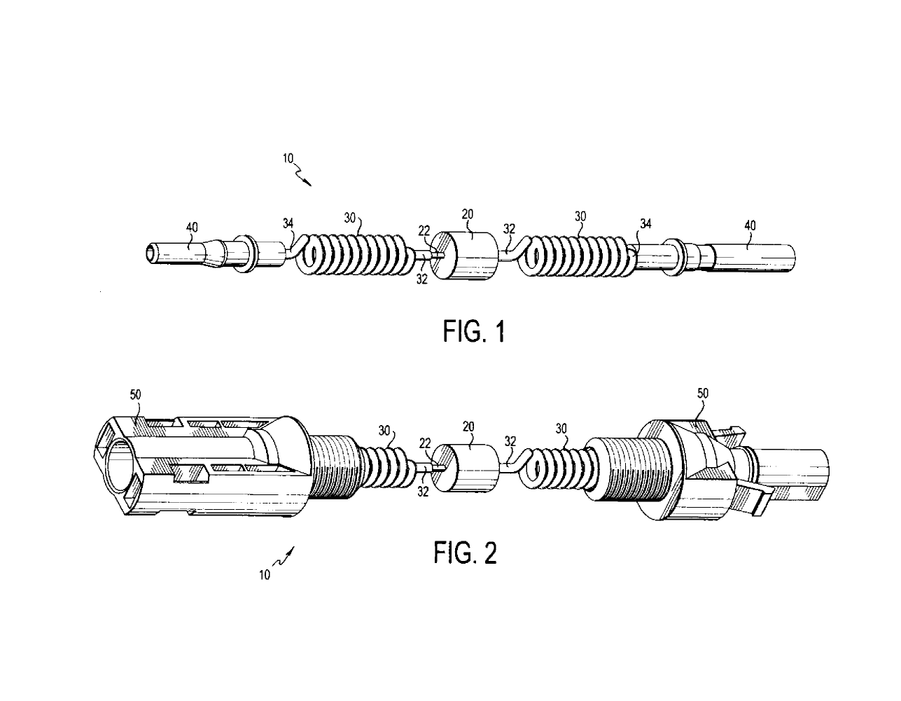

Turning first to FIG. 1, shown therein is a device 10 including a diode 20 having a lead 22 at each of its opposite ends. An axial, leaded rectifier diode 20 is preferred. However, any rectifier or semiconductor diode 20 may be employed. Diode ratings can range from 1 A to 15 A and are generally 600V or 1000V. Electrically conductive coils 30 are positioned at each end of the diode 20. Preferably, the coils 30 are wound or coiled wire manufactured from copper or aluminum or an alloy thereof. The coils include ends 32 that are fixed to the leads 22 of the diode 20 via soldering, welding, brazing, crimping, or other joining means to ensure sound thermal and electrical contact between the coils 30 and the diode 20. Each coil 30 may be air cored (i.e., have no core or have a core formed with non-ferromagnetic material such as plastic or other insulating material) or have a ferromagnetic core (i.e., a core formed with ferrite or other ferromagnetic material). A ferromagnetic core can serve to increase the inductance of the coil 30. The ends 34 of the coils 30 that are not connected to the diode 20 are fixed to device terminals 40 via soldering, welding, brazing, crimping, or other joining means to ensure sound thermal and electrical contact between the coils 30 and the terminals 40. Accordingly, each coil 30 is connected in series between the diode 20 and a terminal 40. A primary function of the coils 30 is to regulate the current that passes through the device 10. Another primary function of the coils 30 is to optimize the transfer of heat to the surrounding environment by efficiently distributing the heat through the device 10.

FIG. 2 shows the device 10 with each of the terminals 40 housed in a separate electrically insulative connector body 50. The terminals 40 are therefore not visible in FIG. 2. The terminals 40 may be electrically connected to the wiring system of a photovoltaic array (not shown) via the connector bodies 50. The respective terminals 40 and connector bodies 50 need not be identical. Rather, each terminal 40 and each connector body 50 may be adapted for the specific use for which it is desired. For example, each connector body 50 may be a male, female, or other type of connector, and each may be adapted to connect to a solar panel, a combiner box, an inverter, or other appropriate assembly. The connector bodies 50 are configured to maintain intimate thermal contact with the terminals 40. Preferably, the connector bodies 50 are formed of a hard, strong material, such as polycarbonate (PC). The connector bodies 50 may be formed separate from the overmold 60, or may be formed integrally with the overmold 60.

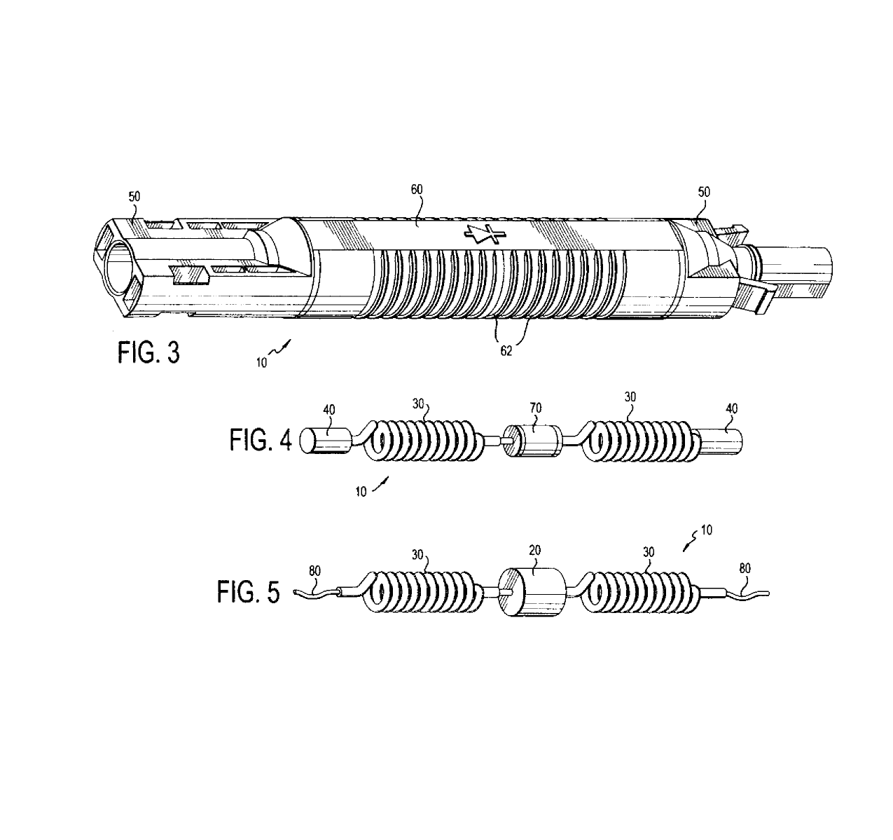

FIG. 3 shows the device 10 with the diode 20 and the coils 30 encapsulated in an electrically insulative overmold 60. The diode 20 and coils 30 are therefore not visible in FIG. 3. The overmold 60 may be formed with a plastic material such as a thermoplastic, thermoset, or combination thereof. A thermoplastic material is preferred, specifically one with a melting temperature below 200° C., such as thermoplastic elastomer (TPE), to ensure that the diode 20 is not damaged during molding. The overmold 60 is configured to ensure intimate thermal contact between the overmold 60, the diode 20, and the coils 30. Heat is transferred from the diode 20 and coils 30 to the overmold 60. The heat is subsequently transferred from the overmold 60 to the surrounding environment through the outside surface of the overmold 60. Accordingly, the outside surface of the overmold 60 may include embossments, protrusions, contours, etchings, or other features disposed thereon to increase the outside surface area of the overmold 60, thus increasing the convective heat transfer properties of the device 10. For example, the outside surface of the overmold 60 may have fins 62 or fin-shaped embossments disposed thereon. The fins 62, for example, may be ring-shaped or partial ring-shaped protrusions that are axially spaced along the length of the overmold 60. Preferably, the material used to form the overmold 60 is such that the thermal conductivity of the overmold 60 is approximately 0.12 to 0.63 W/m·K. Due to the low thermal conductivity of the overmold 60, the use of long, protruding heat sink fins is impractical. Accordingly, the length of the fins 62 may be shorter than a typical metallic heat sink. The overmold 60 also protects the diode 20 and coils 30 from damage that could result from exposure of the diode 20 or coils 30 to the surrounding environment.

Preferably, the encapsulating material is a thermoplastic overmold 60 formed by an injection molding process. However, the encapsulating material is not limited to a specific type of material, nor is it limited to a specific manufacturing process. For example, the encapsulating material may be a compound formed by a potting process.

A primary function of the coils 30 is to regulate the current that passes through the device 10. An unregulated current spike passed through a diode 20, for example, may damage the diode 20, and impair its functionality. The coils 30 act as inductors, thereby reducing current fluctuations within the device 10 and ensuring that the diode 20 and any other devices to which the device 10 is connected experience steady current.

Another primary function of the coils 30 is to optimize the transfer of heat to the surrounding environment by efficiently distributing the heat through the device 10. Accordingly, the coils 30 draw heat from the diode 20 through the leads 22 of the diode, which maintain sound thermal contact with the coils 30. Heat drawn by the coils 30 is transferred to the overmold 60 and consequently to the outside environment. The device 10 is configured such that enough heat is dissipated into the surrounding environment so as to ensure that the terminals 40 do not exceed the required safe temperatures as per the relevant industry standards. Examples of industry standards include UL1703, UL1741, UL6703, UL4248, NEC 2011, CEC Part 1 2009, and similar relevant IEC standards, all of which are incorporated herein by reference. The total heat dissipated by the device 10 is dependent on the current rating of the diode 20 employed by the device 10. Heat (measured in Watts) is generated by the diode 20 and is equal to I²×R (current squared times resistance). The heat is dissipated to the surrounding environment by free convection, wherein heat (in Watts) is equal to k×A×ΔT (convection constant times surface area times temperature difference between ambient air and device surface). Because the standards will dictate the maximum surface temperature and ambient temperature, it follows that increasing the surface area of the device 10 is the only means of increasing the heat dissipation. Therefore, a higher amperage diode 20 requires a larger device 10 to dissipate the heat generated by the diode 20.

The coils 30, therefore, are specifically configured to optimize heat transfer within the device 10. Due to the relatively low conductivity of the overmold 60 (approximately 0.12 to 0.63 W/m·K) as compared to typical current conducting materials (approximately 23 to 388 W/m·K), each coil 30 requires sufficient surface area in contact with the overmold 60 to transfer the required heat from the diode 30 to the overmold 60, rather than transfer the heat from the diode 30 directly through the coil 30 and into the adjacent terminal 40. The coils 30 must be of sufficient length to allow for optimal conduction of heat to the overmold 60, without being too long so as to cause excessive electrical resistance across the device. For each coil 30, the parameters of coil wire diameter, coil wire length, overall coil length, outside coil diameter, number of coil turns, and turn pitch, for example, can be optimized to ensure maximum heat transfer, minimal electrical resistance, and minimum cost. The parameters may vary depending on the power rating of the diode 20 employed in the device. Optimal heat transfer is a balance between minimizing the temperature of the terminals 40 and ensuring the overmold 60 does not exceed industry standard allowable temperatures. Generally, overall coil length, outside coil diameter, and number of coil turns will increase with increasing diode current ratings. The higher the diode current rating, the longer the total coil wire length must be. The parameters are then adjusted to package this total length of wire into a coil 30 that will fit into the design.

In an alternative embodiment of the invention, shown in FIG. 4, the device 10 may include a fuse 70 instead of a diode 20. Any type of axial fuse 70 may be utilized. Fuse current can range from 1 A (or less) to 30 A maximum. In the case in which the device 10 includes a fuse 70, the fuse 70 is incorporated into the device 10 in the same manner as the diode 20 discussed herein. Although, in photovoltaic applications, a device 10 having a fuse 70 may serve a different function than a device 10 having a diode 20, the function of the coils 30 is the same, regardless of whether the device includes a fuse 70 or a diode 20. In a device 10 having a fuse 70, the primary functions of the coils 30 are to regulate the current that passes through the device 10, and to optimize heat transfer from the device 10 to the surrounding environment. In an embodiment of the device 10 comprising a fuse 70, the total heat dissipated by the device 10 is dependent on the current rating of the fuse 70. Therefore, a higher amperage fuse 70 requires a larger device 10 to dissipate the heat generated. The ability of the coils 30 to regulate current through the fuse 70 is particularly advantageous as this ability prevents the fuse 70 from unnecessarily interrupting a circuit as a result of a current spike introduced to the device 10.

In another alternative embodiment, shown in FIG. 5, the device 10 may include wires 80 instead of terminals 40. The wires 80 are electrically connected to the ends 34 of the coils 30. Portions of the wires 80 protrude from the device 10, and those protruding portions may be connected to the wiring system of a photovoltaic array. In an embodiment of the device comprising wires 80, each coil 30 transfers the required heat from the diode 30 or fuse 70 to the overmold 60, rather than transferring the heat from the diode 30 or fuse 70 directly through the coil 30 and into the adjacent wire 80. The use of wires 80 in place of terminals 40 may provide a low cost option for large installations employing the invention.

In yet another alternative embodiment, the device 10 may include only one coil 30 electrically connected to the diode 20. In this embodiment, the lead 22 of the diode 20 not connected to the coil 30 may be connected directly to a terminal 40, or to a wire 80 protruding from the device 10. A device 10 having two coils 30 will generally transfer more heat than a device 10 having one coil 30. However, a device 10 having only one coil 30 may provide sufficient heat transfer in lower amperage applications of the invention.

In yet another alternative embodiment, the device 10 may include a plurality of diodes 20, which form a diode component. The diode component is positioned between, and thermally and electrically connected to the coil 30 or coils 30. When a plurality of diodes 20 is used, the diodes 20 may be connected in series, or parallel, or both. When diodes 20 are connected in series to form a diode component, the voltage ratings of the diodes 20 are added to determine the voltage rating of the diode component. When diodes 20 are connected in parallel to form a diode component, the current ratings of the diodes 20 are added to determine the current rating of the diode component. The use of multiple diodes 20 may allow for the use of diode components having voltage or current ratings that are not readily available in single diode versions.

In yet another alternative embodiment, the current conducting material that electrically connects the leads 22 of the diode 20 or fuse 70 to the terminals 40 or wires 80 need not be wound into a coil 30, but may take on other configurations. An exemplary configuration includes a first strip electrically connecting the leads 22 of the diode 20 or fuse 70 to the terminals 40 or wires 80, the first strip having one or more second strips, perpendicular to the first strip, protruding along the length of the first strip. Other configurations may include, for example, a tube or pipe, or a zigzag pattern.

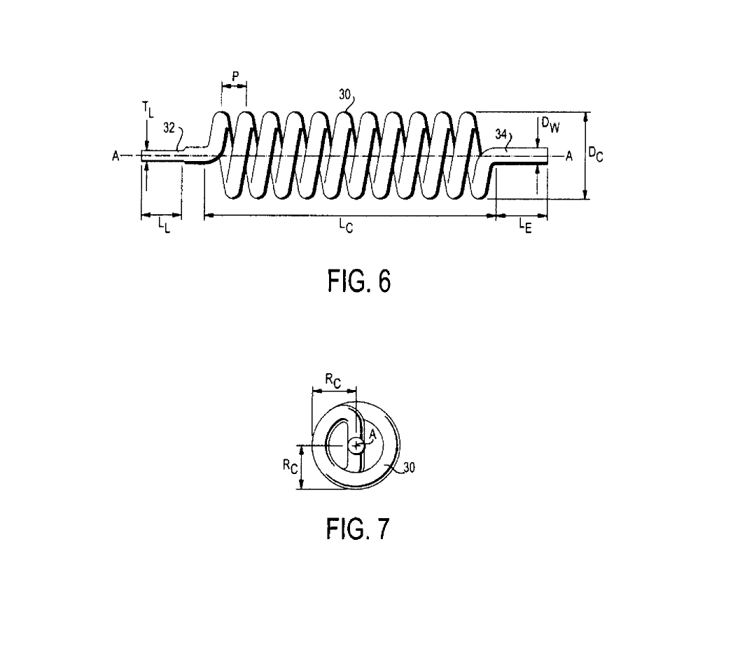

Turning to FIGS. 6 and 7, FIG. 6 shows a side view of the coil 30. FIG. 7 shows the coil 30 with its central longitudinal axis A extending perpendicular to the page. These figures are provided for exemplary purposes only and are not drawn to scale. Furthermore, the parameter values discussed with respect to FIGS. 6 and 7 are provided as examples and are not intended to limit the scope of the invention. FIGS. 6 and 7 show a coil 30 having n turns, where n is equal to five. Additional parameters of the coil 30 include coil length L_{C}, outside coil diameter D_{C}, outside coil radius R_{C}, coil wire diameter D_{W}, coil pitch P, coil end length L_{E}, coil lead length L_{L}, and coil lead thickness T_{L}, wherein the coil pitch P is the distance between corresponding points of two adjacent turns, the coil end length L_{E} is the length of unturned conductive material at an end 32, 34 of the coil 30, and the coil lead length L_{L} is the length of unturned conductive material at an end 32, 34 of the coil 30, in which the current conducting material has been flattened to a thickness T_{L} to facilitate attachment of the diode 20 or the fuse 70 to the coil 32. Another parameter, coil wire length L_{W} (not labeled in figures), is the total length of wire used to form the coil 30. The ends 32, 34 of the coil 30 lie along an axis A, wherein A defines a central longitudinal axis of the coil 30. The ends 32, 34 of the coil 30 need not be identical. Rather, each end 32, 34 may be adapted for the specific use for which it is desired. In an exemplary embodiment of the invention, the coil 30 is configured such that n=5, L_{C}=20 mm, D_{C}=10 mm, R_{C}=5 mm, D_{W}=2 mm, P=4 mm, L_{E}=8 mm, L_{L}=7 mm, and T_{L}=1 mm.

The quantity of heat transferred by the device 10 is determined by the equation

q=k A ΔT,

wherein k is the heat transfer coefficient in W/m²K, A is the outside surface area of the device, and ΔT is the difference between the ambient air temperature and the device surface temperature. For natural convection in air, k can range from 5 W/m²K to 100 W/m²K. In an exemplary embodiment employing a thermoplastic elastomeric material for encapsulation, this design has been shown empirically to have a k value of approximately 25 W/m²K. Assuming an ambient temperature of 40° C. and a maximum surface temperature of 70° C., we calculate a total heat transfer of 5.3 W for a mid-range power version with an outside surface area of 7,067 mm². A high power version with a surface area of 16,557 mm² is capable of dissipating 12.4 W of heat.

Although certain presently preferred embodiments of the disclosed invention have been specifically described herein, it will be apparent to those skilled in the art to which the invention pertains that variations and modifications of the various embodiments shown and described herein may be made without departing from the spirit and scope of the invention. Accordingly, it is intended that the invention be limited only to the extent required by the appended claims and the applicable rules of law.

What is claimed is:

1. A current regulating device comprising:
a circuit element having a first lead and a second lead;
a first coil formed of electrically conductive material, the first coil electrically connected to the first lead; and
an insulative material, the insulative material encapsulating the circuit element and the first coil, and the insulative material maintaining intimate thermal contact with the circuit element and the first coil,
wherein the first coil is configured to draw heat away from the circuit element and into the insulative material.

2. The current regulating device of claim 1, wherein the circuit element comprises a diode.

3. The current regulating device of claim 2, wherein the first coil comprises an air core.

4. The current regulating device of claim 2, wherein the first coil comprises a ferromagnetic core.

5. The current regulating device of claim 2, wherein the first coil and the second lead are electrically connected either to wires protruding from the device or to electrical terminals housed in connector bodies.

6. The current regulating device of claim 5, wherein the wires or the electrical terminals are electrically connected to the wiring system of a photovoltaic array.

7. The current regulating device of claim 2, wherein the insulative material comprises a thermoplastic, thermoset, or combination thereof.

8. The current regulating device of claim 2, wherein an outside surface of the insulative material has features disposed thereon to increase the outside surface area of the device.

9. The current regulating device of claim 2, wherein an outside surface of the insulative material comprises fins or fin-shaped embossments.

10. The current regulating device of claim 2 further comprising:
a second coil formed of electrically conductive material, the second coil electrically connected to the second lead,
wherein the insulative material encapsulates the second coil and maintains intimate thermal contact with the second coil, and
wherein the second coil is configured to draw heat away from the circuit element and into the insulative material.

11. The current regulating device of claim 10, wherein the first coil and the second coil are electrically connected either to wires protruding from the device or to electrical terminals housed in connector bodies.

12. The current regulating device of claim 11, wherein the wires or the electrical terminals are electrically connected to the wiring system of a photovoltaic array.

13. The current regulating device of claim 1, wherein the circuit element comprises a fuse.

14. The current regulating device of claim 13, wherein the first coil comprises an air core.

15. The current regulating device of claim 13, wherein the first coil comprises a ferromagnetic core.

16. The current regulating device of claim 13, wherein the first coil and the second lead are electrically connected either to wires protruding from the device or to electrical terminals housed in connector bodies.

17. The current regulating device of claim 16, wherein the wires or the electrical terminals are electrically connected to the wiring system of a photovoltaic array.

18. The current regulating device of claim 13, wherein the insulative material comprises a thermoplastic, thermoset, or combination thereof.

19. The current regulating device of claim 13, wherein an outside surface of the insulative material has features disposed thereon to increase the outside surface area of the device.

20. The current regulating device of claim 13, wherein an outside surface of the insulative material comprises fins or fin-shaped embossments.

21. The current regulating device of claim 13 further comprising:
a second coil formed of electrically conductive material, the second coil electrically connected to the second lead,
wherein the insulative material encapsulates the second coil and maintains intimate thermal contact with the second coil, and
wherein the second coil is specifically configured to draw heat away from the circuit element and into the insulative material.

22. The current regulating device of claim 21, wherein the first coil and the second coil are electrically connected either to wires protruding from the device or to electrical terminals housed in connector bodies.

23. The current regulating device of claim 22, wherein the wires or the electrical terminals are electrically connected to the wiring system of a photovoltaic array.

24. A current regulating device comprising:
a diode component comprising one or more diodes, the diode component having a first lead and a second lead;
a first coil formed of electrically conductive material, the first coil electrically connected to the first lead; and
an insulative material, the insulative material encapsulating the diode component and the first coil, and the insulative material maintaining intimate thermal contact with the diode component and the first coil,
wherein the first coil is configured to draw heat away from the diode component and into the insulative material.

25. The current regulating device of claim 24 further comprising:
a second coil formed of electrically conductive material, the second coil electrically connected to the second lead,
wherein the insulative material encapsulates the second coil and maintains intimate thermal contact with the second coil, and
wherein the second coil is configured to draw heat away from the diode component and into the insulative material.

26. The current regulating device of claim 25, wherein the first coil and the second coil are electrically connected either to wires protruding from the device or to electrical terminals housed in connector bodies.

27. The current regulating device of claim 26, wherein the wires or the electrical terminals are electrically connected to the wiring system of a photovoltaic array.

28. A device comprising:
a circuit element having a first lead and a second lead;
a first electrically conductive material electrically connected to the first lead; and
an insulative material, the insulative material encapsulating the circuit element and the first electrically conductive material, and the insulative material maintaining intimate thermal contact with the thermal element and the first electrically conductive material,
wherein the first electrically conductive material is configured to draw heat away from the circuit element and into the insulative material.

29. The device of claim 28, wherein the first electrically conductive material comprises a first strip having one or more second strips protruding along the length of the first strip.

30. The device of claim 28, wherein the first electrically conductive material comprises a tube or a pipe.

31. The device of claim 28, wherein the first electrically conductive material comprises a zigzag pattern.

32. The device of claim 28, wherein the circuit element comprises a diode.

33. The device of claim 32, wherein the first electrically conductive material and the second lead are electrically connected either to wires protruding from the device or to electrical terminals housed in connector bodies.

34. The device of claim 33, wherein the wires or the electrical terminals are electrically connected to the wiring system of a photovoltaic array.

35. The device of claim 32, wherein the insulative material comprises a thermoplastic, thermoset, or combination thereof.

36. The device of claim 32, wherein an outside surface of the insulative material has features disposed thereon to increase the outside surface area of the device.

37. The device of claim 32, wherein an outside surface of the insulative material comprises fins or fin-shaped embossments.

38. The device of claim 32 further comprising:
a second electrically conductive material electrically connected to the second lead,
wherein the insulative material encapsulates the second coil and maintains intimate thermal contact with the second electrically conductive material, and
wherein the second electrically conductive material is configured to draw heat away from the circuit element and into the insulative material.

39. The device of claim 38, wherein the first electrically conductive material and the second electrically conductive material are electrically connected either to wires protruding from the device or to electrical terminals housed in connector bodies.

40. The device of claim 39, wherein the wires or the electrical terminals are electrically connected to the wiring system of a photovoltaic array.

41. The device of claim 28, wherein the circuit element comprises a fuse.

42. The device of claim 41, wherein the first electrically conductive material and the second lead are electrically connected either to wires protruding from the device or to electrical terminals housed in connector bodies.

43. The device of claim 42, wherein the wires or the electrical terminals are electrically connected to the wiring system of a photovoltaic array.

44. The device of claim 41, wherein the insulative material comprises a thermoplastic, thermoset, or combination thereof.

45. The device of claim 41, wherein an outside surface of the insulative material has features disposed thereon to increase the outside surface area of the device.

46. The device of claim 41, wherein an outside surface of the insulative material comprises fins or fin-shaped embossments.

47. The device of claim 41 further comprising:
a second electrically conductive material electrically connected to the second lead,
wherein the insulative material encapsulates the second coil and maintains intimate thermal contact with the second electrically conductive material, and
wherein the second electrically conductive material is configured to draw heat away from the circuit element and into the insulative material.

48. The device of claim 47, wherein the first electrically conductive material and the second electrically conductive material are electrically connected either to wires protruding from the device or to electrical terminals housed in connector bodies.

49. The device of claim 48, wherein the wires or the electrical terminals are electrically connected to the wiring system of a photovoltaic array.
